(19) United States
(12) Patent Application Publication
(10) Pub. No.: US 2012/0279546 A1
(43) Pub. Date: Nov. 8, 2012

(54) SOLAR CELL CONNECTOR ELECTRODE, SOLAR CELL MODULE AND METHOD FOR ELECTRICALLY CONNECTING A PLURALITY OF SOLAR CELLS

(75) Inventors: Martin Kutzer, Penig (DE); Olaf Storbeck, Dresden (DE); Harald Hahn, Dresden (DE); Holger Neuhaus, Freiberg (DE); Matthias Georgi, Dresden (DE)

(73) Assignee: SOLARWORLD INNOVATIONS GMBH, Freiberg (DE)

(21) Appl. No.: 13/410,460

(22) Filed: Mar. 2, 2012

(30) Foreign Application Priority Data
Mar. 3, 2011 (DE) 10 2011 001 061.0

(51) Int. Cl. H01L 31/05; H01L 31/18

(52) U.S. Cl. 136/244; 29/825

(57) ABSTRACT

In various embodiments, a solar cell connector electrode may include a multiplicity of electrically conductive solar cell connector elements arranged alongside one another; and a plurality of electrically non-conductive and isolated from one another, planar elements on which the electrically conductive solar cell connector elements are arranged. Solar cell connector element isolating locations are provided in regions on the planar elements, such that, by means of a respective solar cell connector element isolating location, a respectively electrically conductive solar cell connector element is divided into a plurality of, preferably two, solar cell connector partial elements electrically isolated from one another.

### CROSS-REFERENCE TO RELATED APPLICATION

This application claims priority to German Patent Application Serial No. 10 2011 001 061.0-33, which was filed Mar. 3, 2011, and is incorporated herein by reference in its entirety.

### TECHNICAL FIELD

Various embodiments relate to a solar cell connector electrode, a solar cell module and a method for electrically connecting a plurality of solar cells.

### BACKGROUND

Various concepts for rear side contact solar cells are known:
a metal wrap-through (MWT) solar cell;

an emitter wrap-through (EWT) solar cell, wherein the MWT solar cell and the EWT solar cell are disclosed in Haverkamp et al., 19th European Photovoltaic Solar Energy Conference, Jun. 7 to 11, 2004, Paris, France; and
a back-junction solar cell, disclosed in DE 195 25 720 A1.

The advantages of such rear side contact solar cells are primarily the result of the reduced shading on the sun side of the solar cell. The base contacts and emitter contacts are both applied to the rear side of the solar cell. In this case, various arrangements are known.

One possibility is a strip-like arrangement of the contacts on the rear side of the solar cell. Another method provides two metallization structures (IBC) intermeshed in a comb-like manner (described in DE 195 25 720 A1). In this case, the current is passed via the intermeshed comb structures to collecting structures at the edge of the solar cell. The conductivity of the comb structures is particularly problematic in this case, said conductivity having to be increased in order to limit ohmic losses that occur. The approaches are usually based on electrolytically reinforcing the contact structures or using cost-intensive metal pastes.

In the case of an interconnection of the solar cells with a strip-like arrangement of the contact structures, the interconnection in a solar cell module can occur by means of conventional connector structures. However, it can be advantageous here to use a high number of contact strips. It is therefore possible to reduce power losses as a result of ohmic resistances in the solar cell. By way of example, depending on the cell technology, 10 to 30 contact strips and a corresponding number of connector structures can be provided. In this case, the positioning of the connectors usually proves to be difficult. The individual elements have to be supplied, fixedly held and adjoined.

DE 10 2008 043 833 A1 describes a method wherein the solar cell connectors are drawn over the length of a plurality of solar cells and connected. Excess connections are then separated, such that short circuits produced arc removed again. What is disadvantageous in that case is that the separating step is carried out on solar cells that have already been interconnected. This requires a complex technology which detects the position of the locations to be separated and then reliably separates the latter. Furthermore, the space between the solar cells is not arbitrarily large, and so the separating gap also cannot be made arbitrarily large. If slips then occur during the encapsulation of the solar cells, short circuits can arise as a result of contact wires that have already been separated making touching contact. A further disadvantage is the fixing of the contact wires. Over the complete solar cell module length, displacements of the solar cell connectors can occur, such that the solar cell connectors no longer lie parallel to one another, and short circuits of base and emitter contacts can likewise arise again as a result.

The interconnection of the IBC structures is not possible with the method disclosed in DE 10 2008 043 833 A1, but solutions already exist for this purpose. Thus, DE 10 2008 031 279 A1 describes a method wherein the emitter contact collecting structure of the first solar cell is respectively connected to the base contact collecting structure of the following solar cell. A disadvantage is that the current is only collected via the contact structures of the solar cell. This causes high resistance losses in the contact structures.

### SUMMARY

In various embodiments, a solar cell connector electrode may include a multiplicity of electrically conductive solar cell connector elements arranged alongside one another; and a plurality of electrically non-conductive and isolated from one another, planar elements on which the electrically conductive solar cell connector elements are arranged. Solar cell connector element isolating locations are provided in regions on the planar elements, such that, by means of a respective solar cell connector element isolating location, a respectively electrically conductive solar cell connector element is divided into a plurality of, preferably two, solar cell connector partial elements electrically isolated from one another.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a rear side view of a rear side contact solar cell in accordance with various exemplary embodiments;

FIG. 2 shows a rear side view of a rear side contact solar cell in accordance with various exemplary embodiments;

FIG. 3 shows a solar cell electrode in accordance with various exemplary embodiments at a first point in time of its production;

FIG. 4 shows a solar cell electrode in accordance with various exemplary embodiments at a second point in time of its production;

FIG. 5 shows a device for producing a solar cell electrode in accordance with various exemplary embodiments;

FIG. 6 shows an apparatus for prefabricating a solar cell electrode in accordance with various exemplary embodiments;

FIG. 7 shows an arrangement with a plurality of solar cells in accordance with various exemplary embodiments;

FIG. 8 shows a joining device, designed for carrying out a continuous joining process for a solar cell electrode placed onto the rear sides of a plurality of solar cells, in accordance with various exemplary embodiments;

FIG. 9 shows a joining device, designed for carrying out a continuous joining process for a solar cell electrode placed onto the rear sides of a plurality of solar cells, in accordance with various exemplary embodiments;

FIG. 10 shows a device with a plurality of solar cells and a solar cell electrode in accordance with various exemplary embodiments;

FIG. 11 shows an interconnection of solar cells with an unequal number of positive contact regions and negative contact regions in accordance with various exemplary embodiments;

FIG. 12 shows solar cell connector element isolating locations in accordance with various exemplary embodiments in accordance with FIG. 11;

FIG. 13 shows a plurality of solar cells interconnected in accordance with the process illustrated in FIG. 11 in accordance with various exemplary embodiments;

FIG. 14 shows a solar cell electrode in accordance with various exemplary embodiments;

FIG. 15 shows a method for producing a solar cell connector electrode in accordance with various exemplary embodiments in a flowchart; and

FIG. 16 shows a method for electrically connecting a plurality of solar cells in accordance with various exemplary embodiments in a flowchart.

### DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

The word “over” used with regards to a deposited material formed “over” a side or surface, may be used herein to mean that the deposited material may be formed “directly on”, e.g. in direct contact with, the implied side or surface. The word “over” used with regards to a deposited material formed “over” a side or surface, may be used herein to mean that the deposited material may be formed “indirectly on” the implied side or surface with one or more additional layers being arranged between the implied side or surface and the deposited material.

In the following detailed description, reference is made to the accompanying drawings, which form part of this description and show for illustration purposes specific embodiments in which the invention can be implemented. In this regard, direction terminology such as, for instance, “at the top”, “at the bottom”, “at the front”, “at the back”, “front”, “rear”, etc., is used with reference to the orientation of the figure(s) described. Since components of embodiments can be positioned in a number of different orientations, the direction terminology serves for illustration purposes and is not restrictive in any way at all. It goes without staying that other embodiments can be used and structural or logical changes can be made, without departing from the scope of protection of the present invention. It goes without saying that the features of the various exemplary embodiments described herein can be combined with one another, unless specifically indicated otherwise. Therefore, the following detailed description should not be interpreted in a restrictive sense, and the scope of protection of the present invention is defined by the appended claims.

In the context of this description, the terms “connected”, and “coupled” are used to describe both a direct and an indirect connection and also a direct or indirect coupling. In the figures, identical or similar elements are provided with identical reference symbols, insofar as this is expedient.

In various exemplary embodiments, a solar cell should be understood to mean a device which directly converts radiation energy of predominantly visible light (for example at least part of the light in the visible wavelength range of approximately 300 nm to approximately 1150 nm; it should be noted that ultraviolet (UV) radiation and/or infrared (IR) radiation can additionally be converted as well), for example of sunlight, into electrical energy by means of the so-called photovoltaic effect.

In various exemplary embodiments, a solar cell module is understood to be an electrically connectable device including a plurality of solar cells (which are interconnected with one another in series and/or in parallel), and optionally including protection against the weather (for example glass), an embedding and a framing.

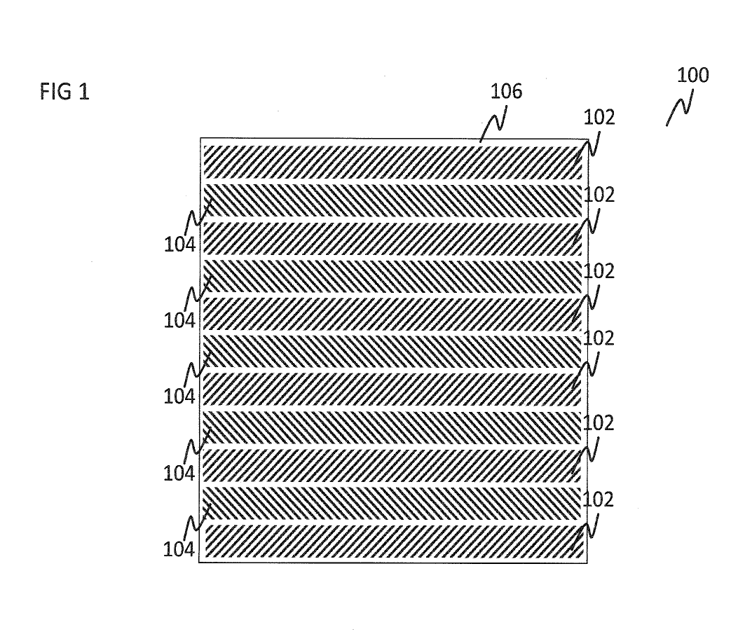

FIG. 1 shows a rear side view of a rear side contact solar cell 100 in accordance with various exemplary embodiments. The rear side contact solar cell 100 in accordance with FIG. 1 includes a strip-shaped contact arrangement, wherein a base contact 102 and an emitter contact 104 are respectively arranged alternately on the rear side 106 (i.e. on the side facing away from the sun side of the rear side contact solar cell 100) of the rear side contact solar cell 100. The base contact 102 or the base contacts 102 is or are electrically isolated, for example electrically insulated, from the emitter contact 104 or the emitter contacts 104.

In various exemplary embodiments, the rear side contact solar cell 100 includes a substrate. The substrate may include or consist of at least one photovoltaic layer. Alternatively, at least one photovoltaic layer may be arranged on or above the substrate. The photovoltaic layer may include or consist of semiconductor material (such as, for example, silicon), a compound semiconductor material (such as, for example, a III-V compound semiconductor material (such as, for example, GaAs), a II-VI compound semiconductor material (such as, for example CdTe) or a I-III-V compound semiconductor material (such as, for example, copper indium disulfide)). As a further alternative, the photovoltaic layer may include or consist of organic material. In various exemplary embodiments, the silicon may include or consist of monocrystalline polycrystalline silicon, amorphous silicon, and/or microcrystalline silicon. In various exemplary embodiments, the photovoltaic layer may include or consist of a semiconductor junction structure such as, for example, a pn junction structure, a pin junction structure, a Schottky-like junction structure, and the like. The substrate and/or the photovoltaic layer may be provided with a basic doping of a first conduction type.

In various exemplary embodiments, the basic doping in the solar cell substrate may have a doping concentration (for example of a doping of the first conduction type, for example of a doping of the p conduction type, for example with dopant from main group III. of the periodic system, for example of a doping with boron (B)) in a range of approximately 10¹³ cm⁻³ to 10¹⁸ cm ⁻³, for example in the range of approximately 10¹⁴ cm ⁻³ to 10¹⁷ cm ⁻³, for example in a range of approximately 10¹⁵ cm ⁻³ to 2*10¹⁶ cm ⁻³. That region of the solar cell substrate which is provided with the basic doping is also designated hereinafter as the base region. In various exemplary embodiments, the base region is electrically connected, to put it another way contact-connected, to one or a plurality of base contacts 102.

In various exemplary embodiments, in the substrate of the rear side contact solar cell 100 it is possible to form an emitter region, doped with dopant of a second conduction type, wherein the second conduction type is opposite to the first conduction type, for example with dopant of the n conduction type, for example with dopant from main group V. of the periodic system, for example with phosphorus (P). In various exemplary embodiments, the emitter region is electrically connected, to put it another way contact-connected, to one or a plurality of emitter contacts 104.

In various exemplary embodiments, the sheet resistance in the emitter region is in a range of approximately 60 ohms/sq to approximately 300 ohms/sq, for example in a range of approximately 70 ohms/sq to approximately 200 ohms/sq, for example in a range of approximately 80 ohms/sq to approximately 120 ohms/sq.

The solar cell substrate may be produced from a solar cell wafer and can have, for example, a round shape such as, for example, a circular shape or an elliptical shape or a polygonal shape such as, for example, a square shape. In various exemplary embodiments, however, the solar cells of the solar cell module may also have a non-square shape. In these cases, the solar cells of the solar cell module may be formed for example by separating (for example cutting) and thus dividing one or a plurality of solar cell(s) (also designated in terms of the form thereof as standard solar cell) to form a plurality of non-square or square solar cells. In various exemplary embodiments, provision can be made in these cases for implementing adaptations of the contact structures in the standard solar cell; by way of example, rear side transverse structures can additionally be provided.

In various exemplary embodiments, the solar cell may have the following dimensions: a width in a range of approximately 5 cm to approximately 50 cm, a length in a range of approximately 5 cm to approximately 50 cm, and a thickness in a range of approximately 100 μm to approximately 300 μm.

In various exemplary embodiments, the base contact or base contacts 102 and/or the emitter contact or emitter contacts 104 are embodied in the form of metallization structures and include, for example, one or a plurality of metals or one or a plurality of metal alloys.

In various exemplary embodiments, the base contact or base contacts 102 and/or the emitter contact or emitter contacts 104 may include or consist of, for example, silver, copper, aluminum, nickel, cobalt, tin, titanium, palladium, tantalum, gold, platinum or any desired combination or alloy of these materials. In various exemplary embodiments, the base contact or base contacts 102 and/or the emitter contact or emitter contacts 104 may include or consist of silver or nickel. In various exemplary embodiments, the base contact or base contacts 102 and/or the emitter contact or emitter contacts 104 may include or consist of a stack of different metals, for example nickel on titanium, silver on titanium, silver on nickel or, for example, a layer stack formed from titanium-palladium-silver, or a stack of titanium or nickel (both act as a diffusion barrier in this case) with copper arranged thereon.

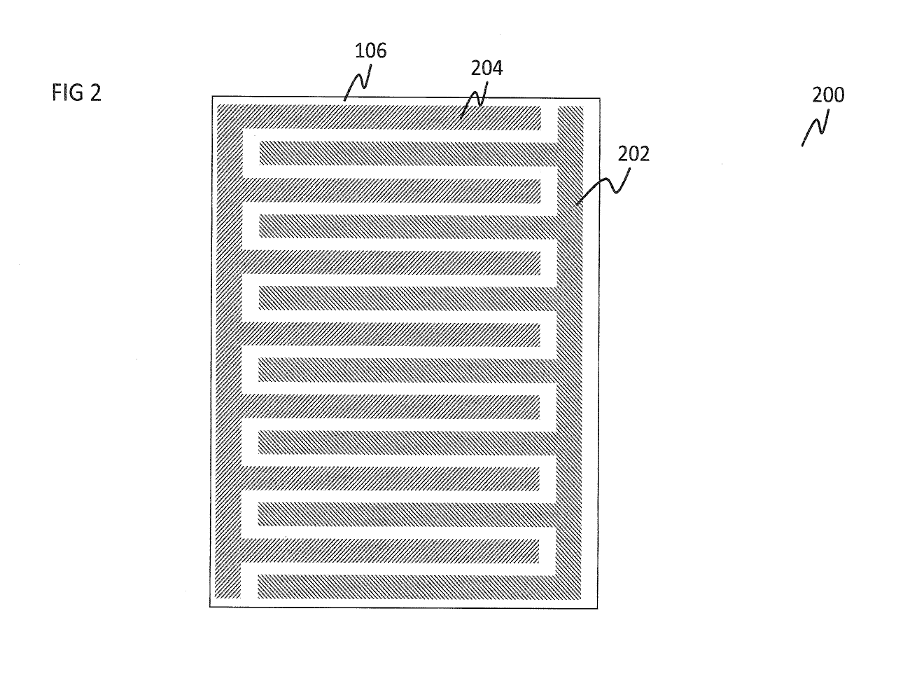

FIG. 2 shows a rear side view of a rear side contact solar cell 200 in accordance with various exemplary embodiments. The rear side contact solar cell 200 in accordance with FIG. 2 is similar to the rear side contact solar cell 100 in accordance with FIG. 1, and so, in order to avoid repetition, reference is made to the description of the features of the rear side contact solar cell 100 in accordance with FIG. 1, which likewise applies to the rear side contact solar cell 200 in accordance with FIG. 2 apart from the differences explained below.

In the case of the rear side contact solar cell 200 in accordance with FIG. 2, the base contact 202 and the emitter contact 204 are embodied such that they are intermeshed in a comb-shaped manner illustratively in the form of an interdigital contact arrangement (IBC). In this exemplary embodiment, too, the base contact 202 and the emitter contact 204 are electrically insulated from one another.

It should be pointed out that in the exemplary embodiments described above, the base region is p-doped, for example, and the emitter region is n-doped. However, in alternative exemplary embodiments, provision is likewise made for the base region to be n-doped, for example, and the emitter region to be p-doped. In such exemplary embodiments, the base contact or base contacts 202 and/or the emitter contact or emitter contacts 204 may, for example, include or consist of aluminum or nickel, optionally with solder material applied on the aluminum (alternatively, the solder material can be applied on the solar cell connectors applied and soldered later).

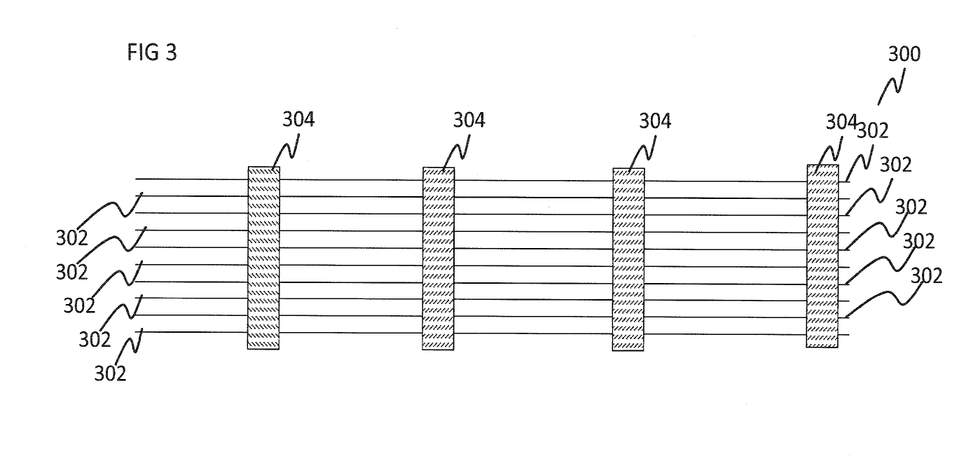

FIG. 3 shows a solar cell electrode 300 in accordance with various exemplary embodiments at a first point in time of its production.

In various exemplary embodiments, the solar cell electrode 300 includes a multiplicity of electrically conductive solar cell connector elements 302 arranged alongside one another, for example implemented as contact wires (also designated as solar cell connector wires) 302 and/or contact ribbons (also designated as solar cell connector ribbons) 302.

The contact wires 302 or contact ribbons 302 for electrically connecting two solar cells 100, 200 may be connected to the emitter contact or emitter contacts 104, 204 on the rear side of a first solar cell 100, 200 of respectively two mutually adjacent solar cells 100, 200 and to the base contact or base contacts 102, 202 on the rear side of a second solar cell 100, 200 of respectively two mutually adjacent solar cells 100, 200. The contact wires 302 or contact ribbons 302 are designed for collecting and transferring electrical energy which has been generated by the photovoltaic layer of a respective solar cell 100, 200.

The contact wires 302 or contact ribbons 302 may include or consist of electrically conductive material, for example metallically conductive material. In various exemplary embodiments, the contact wires 302 or contact ribbons 302 may include or consist of one or a plurality of metallic materials, for example of one or a plurality of the following metals: Cu, Al, Au, Pt, Ag, Pb, Sn, Fe, Ni, Co, Zn, Ti, Mo, W, and/or Bi. In various exemplary embodiments, the contact wires 302 or contact ribbons 302 may include or consist of a metal selected from the group consisting of: Cu, Au, Ag, Pb, and Sn. In various exemplary embodiments, the contact wires 302 or contact ribbons 302 may have, in principle, any desired cross-sectional shape such as, for example, a round (for example circular) shape, an oval shape, a triangular shape, a rectangular shape (for example a square shape), or any other suitable polygonal shape. In various exemplary embodiments, the contact wires 302 or contact ribbons 302 may include a metal, for example nickel, copper, aluminum and/or silver, or some other suitable metal or metal alloy, for example brass. Furthermore, the contact wires 302 or contact ribbons 302 may be or have been coated with a metal or a metal alloy, for example with silver, Sn and/or nickel, and/or a solder coating, including or consisting, for example, of Sn, SnPb, SnCu, SnCuAg, SnPbAg, SnBi. In various exemplary embodiments, a multiplicity of contact wires 302 or contact ribbons 302 may be provided in a respective solar cell electrode 300, for example a number in a range of approximately 5 to approximately 60, for example in a range of approximately 10 to approximately 50, for example in a range of approximately 20 to approximately 40, for example approximately 30. In various exemplary embodiments, the contact wires 302 or contact ribbons 302 of the prefabricated solar cell electrode in accordance with various exemplary embodiments are soldered to the metallization structures, for example the emitter contact or emitter contacts 104, 204 and/or the base contact or base contacts 102, 202 in a process carried out later. In order to improve the linking of the contact wires 302 or contact ribbons 302 to the metallization structures, the latter may be presoldered, for example, by a wave soldering method.

In various exemplary embodiments, the solar cell electrode 300 includes a plurality of electrically non-conductive and, for example isolated from one another, planar elements 304 on which the electrically conductive solar cell connector elements 302 are arranged, for example adhesively bonded. In various exemplary embodiments, the electrically conductive solar cell connector elements 302 may thus be connected adhesively, for example, to the planar elements 304. In various exemplary embodiments, the electrically non-conductive planar elements 304 may be or have been formed by, for example, a continuous element, for example a continuous adhesive film, which can be provided, for example, from a role illustratively in the form of a “continuous tape”. The electrically non-conductive planar elements 304 can be perforated, for example, or else be connected to one another only in individual partial regions, for example by means of connecting webs.

In various exemplary embodiments, the planar elements 304 may be embodied in strip-shape fashion, for example having a rectangular shape in plan view. Alternatively, it is possible to provide any other shape for the planar elements 304, for example an elliptical shape in plan view. In various exemplary embodiments, the planar elements 304 may have a length corresponding precisely to the width of the solar cell 100. In various exemplary embodiments, the planar elements 304 may have a width in a range of approximately 0.2 cm to approximately 5 cm, for example a width in a range of approximately 0.5 cm to approximately 3 cm, for example a width in a range of approximately 1 cm to approximately 2 cm.

In various exemplary embodiments, the planar elements 304 may be arranged relative to the electrically conductive solar cell connector elements 302 at an angle, for example in a manner crossing the solar cell connector elements 302. In various exemplary embodiments, the planar elements 304 may be arranged transversely (i.e. for example at an angle of approximately 90°) with respect to the electrically conductive solar cell connector elements 302.

In various exemplary embodiments, the planar elements 304 may be produced from plastic film, even though all other suitable, for example flexible, electrically insulating materials may alternatively be provided. In various exemplary embodiments, the planar elements 304 may be produced from self-adhesive plastic film. In various exemplary embodiments, the planar elements 304 may be produced from (polymer) materials (in various exemplary embodiments, the polymers, which are also designated as base polymers, may additionally be or have been admixed with UV stabilizers and antioxidants—in addition, these may also contain inorganic fillers such as silicon dioxide or aluminum oxide and corresponding colorants for use in modules having a black rear side film). In various exemplary embodiments, the planar elements 304 may be produced from plastic film composed of all solar cell module embedding materials known per se (for example ethylene vinyl acetate, silicones, aliphatic polyurethanes, polyvinyl butyral). In various exemplary embodiments, the planar elements 304 may be produced from hot melt adhesives such as, for example, ethylene vinyl acetate, polyamides (the latter are resistant to high temperatures), polyester, polyolefins, etc. In various exemplary embodiments, the electrically conductive solar cell connector elements 302 may be or have been adhesively bonded between film strips with conventional 2-component adhesives such as polyurethanes, silicones or epoxides or the adhesives may be or have been cured by means of UV or heat. Furthermore, these materials may be applied to structured reflective films for additional light directing in the solar cell modular (e.g. composed of metals such as aluminum or else to dielectric mirrors).

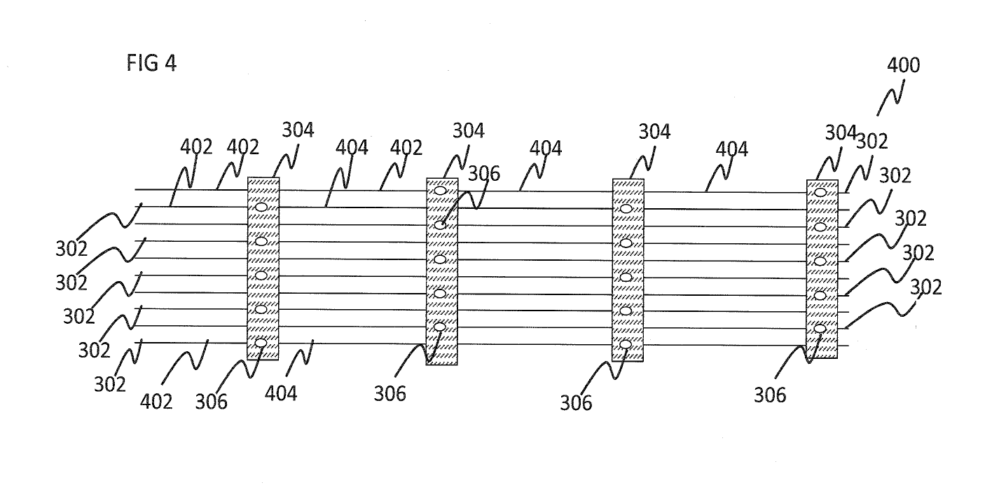

FIG. 4 shows the solar cell electrode 300 in accordance with various exemplary embodiments at a second point in time of its production.

In various exemplary embodiments, as illustrated in FIG. 4, an electrical isolation can be provided for the electrically conductive solar cell connector elements 302 in regions on the planar elements 304 in such a way that respectively one or a plurality of base contacts 102, 202 of a first solar cell 100, 200 of respectively two mutually adjacent solar cells 100, 200 is or are electrically connected by means of a solar cell connector element 302 to one or a plurality of emitter contacts 104, 204 of a second solar cell 100, 200 of respectively two mutually adjacent solar cells 100, 200, but is or are electrically insulated from each base contact 102, 202 of the second solar cell 100, 200. Furthermore, in various exemplary embodiments, an electrical isolation may be provided for the electrically conductive solar cell connector elements 302 in regions on the planar elements 304 in such a way that respectively one or a plurality of emitter contacts 104, 204 of the first solar cell 100, 200 of respectively two mutually adjacent solar cells 100, 200 is or are electrically connected by means of a solar cell connector element 302 to one or a plurality of base contacts 102, 202 of the second solar cell 100, 200 of respectively two mutually adjacent solar cells 100, 200, but is or are electrically insulated from each emitter contact 104, 204 of the second solar cell 100, 200.

Said electrical isolation can be achieved by solar cell connector element isolating locations 306 correspondingly provided in regions on the planar elements 304, such that, by means of a respective solar cell connector element isolating location 306, a respective electrically conductive solar cell connector element 302 is divided into two solar cell connector partial elements 402, 404 electrically isolated from one another. In various exemplary embodiments, one solar cell connector element isolating location 306 or a plurality of solar cell connector element isolating locations 306 may be arranged in the region of a planar element 304 on every second solar cell connector element 302. The solar cell connector element isolating locations 306 may be formed by separating out pieces of the respective solar cell connector elements 302 (for example in the form of contact wires or contact ribbons), for example by means of a laser, by means of stamping or by means of some other suitable process.

In various exemplary embodiments, illustratively a multiplicity of substantially parallel solar cell connector elements 302 (for example in the form of contact wires (also designated as connector wires) 302 or contact ribbons (also designated as connector ribbons) 302—also designated hereinafter as connector array—may in each case be adhesively bonded with a self-adhesive plastic film. This may be done on both sides or on one side. The application of a first adhesive film and optionally of a second adhesive film may be effected simultaneously or in two steps.

Afterward, in a first isolating step, a first solar cell connector element 302 is respectively isolated from two adjacent solar cell connector elements 302 and, in a second isolating step, a second solar cell connector element 302 is respectively isolated from two adjacent solar cell connector elements 302.

In various exemplary embodiments, the distance between the planar elements 304 (for example the adhesive films) corresponds precisely to the distance between the solar cell interspaces in a solar cell module in which the solar cells are incorporated. In the case of solar cells having an IBC contact structure (such as, for example, a solar cell 200 in accordance with FIG. 2), a plurality of solar cell connector element isolating locations 306 are provided per solar cell.

Therefore, illustratively the fabrication of the electrode tape 300, i.e. of the solar cell electrode 300 in accordance with various exemplary embodiments is illustrated schematically in FIG. 3 and FIG. 4. The electrode tape 300 may have the width of a solar cell 100, 200, but it may also be fabricated to the full width of a solar cell module, such that all the solar cells 100, 200 in the solar cell module can be processed in parallel.

Illustratively, in various exemplary embodiments, a tape-type solar cell electrode 300 for interconnecting rear side contact solar cells 100, 200 is fashioned in such a way that a multiplicity of connector elements 302 (ribbon or wire) running substantially parallel are fixed for example by adhesive plastic films (generally by electrically non-conductive planar elements 304), and isolating locations 306 are inserted in a targeted manner in a region of the plastic film (generally electrically non-conductive planar element 304).

The adhesive films may be fashioned adhesively on one side or on both sides. An adhesive film that is adhesive on both sides has the advantage that the solar cell electrode 300 can be mechanically fixed on the solar cells 100, 200 before the electrical contact-connection of the solar cell connector elements 302 (for example in the form of contact wires or contact ribbons) is effected.

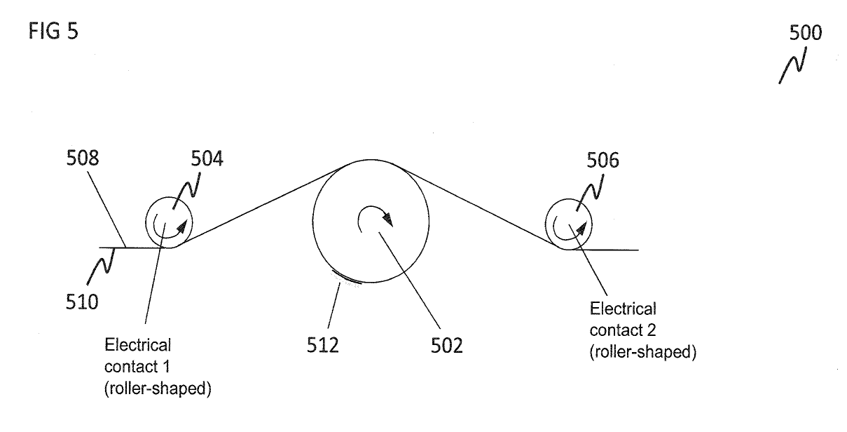

FIG. 5 shows a device 500 for producing an intermediate product of a solar cell electrode in accordance with various exemplary embodiments. The device 500 may be designed for producing a solar cell electrode by means of fusion of a connector array in a hot melt adhesive.

The device 500 may include a main roller 502 and also a first electrically conductive contact roller 504 at an entrance of the device 500 and a second electrically conductive contact roller 506 at an exit of the device 500. A connector array 508 including a multiplicity of solar cell connector elements 302 (for example in the form of contact wires or contact ribbons) arranged alongside one another (for example parallel to one another) is fed on a carrier 510, for example on a conveyor belt 510, to the first electrically conductive contact roller 504 (alternatively without a carrier 510), is electrically heated there and then passed on to the main roller 502. To put it another way, in various exemplary embodiments, the connector array 508 is guided via two electrically conductive rollers 504, 506. In this case, the contact rollers 504 and 506 serve, for example, as contact elements via which an electric current flow is produced through ₜhe solar cell connector elements 302. In this way, the solar cell connector elements 302 (for example in the form of contact wires or contact ribbons) are electrically heated by the resistance of the solar cell connector elements 302. Said solar cell connector elements 302 (for example in the form of contact wires or contact ribbons) may then be guided via a further roller (the main roller 502), which has the same circumference as the cell distance between two solar cells in the solar cell module to be produced. From a separating apparatus (not illustrated) (for example implemented in the form of a separating roller) correspondingly prefabricated electrically non-conductive planar elements 512 (for example films, for example including or consisting of a hot melt adhesive or thermoplastic) are applied to the main roller 502, which elements were cut to size for example by means of a cutting roller (not illustrated). The exemplary film strips 512 may either themselves have a low residual tack, such that they adhere to the main roller 502, or they are sucked on, for example by means of vacuum. The heated connector array 508 fuses into the hot melt adhesive and is fixed in this way. The hot melt adhesive film 512 can be an EVA film 512, for example, such as is usually used for encapsulating the solar cell modules. Optionally, a further layer or film may be or have been applied to the hot melt adhesive layer, said further layer or film having a light capturing structure or being colored in order to cover the contacts between the solar cells. In various exemplary embodiments, provision may furthermore be made for heating the central roller, to put it another way the main roller 502, and completely melting the hot melt adhesive in order to press the solar cell connector elements 302 (for example in the form of contact wires or contact ribbons) into it.

Afterward, the isolating locations 306 may be formed by means of a separating apparatus (not shown) (for example a laser or a stamping apparatus).

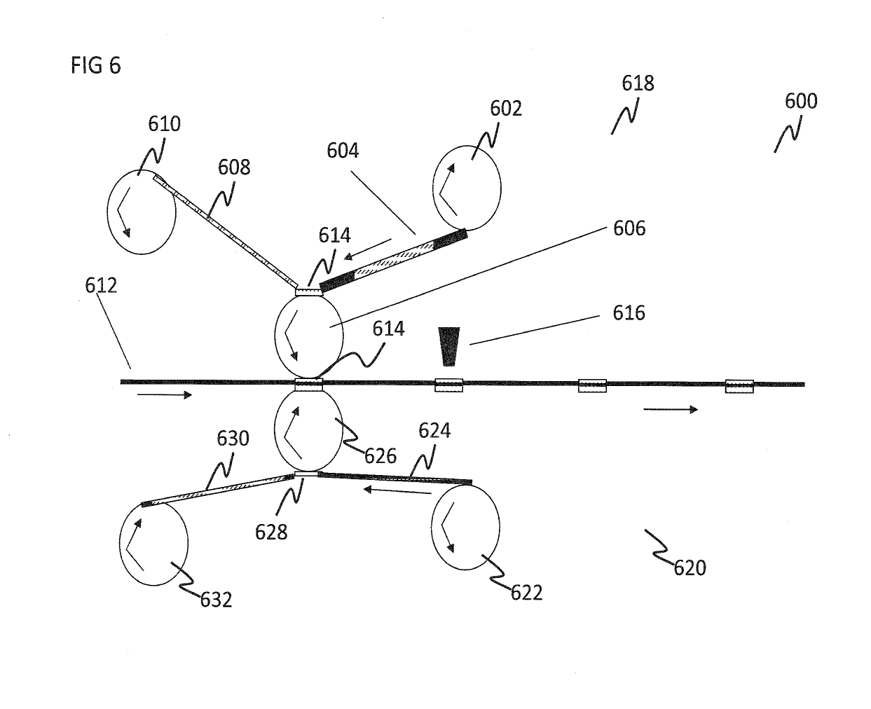

FIG. 6 shows an apparatus 600 for prefabricating a solar cell electrode in accordance with various exemplary embodiments.

From a film roll 602 or film roller 602, a film 604, for example a plastic film 604, for example a self-adhesive plastic film 604, is brought to a transfer roll 606 or transfer roller 606, where a piece of film 604 of corresponding width is cut out or stamped by means of a cutting roller, for example. For this purpose, it is provided that the film 604 does not run continuously, but rather is conveyed in a step-by-step manner. The residual film 608 remaining after the respective planar element 614 has been cut out (to which element the solar cell connector elements (for example in the form of contact wires or contact ribbons) from the connector array 612 are applied) may in turn be wound on to a roll 610 (also designated as residual film roll) or run directly into a supply container (not shown).

Alternatively, film pieces 614 may also be prepared in an additional process step and then be placed on to the transfer roll 606 or transfer roller 606.

The film pieces 614 are adhesively bonded at corresponding distances on to the connector array 612 and thus on to the solar cell connector elements (for example in the form of contact wires or contact ribbons). This may be done on both sides or on one side. The distances may be set by means of a dimensioning of the circumference of the transfer roll 606 or transfer roller 606 and the positions of the film pieces 614 on the transfer roll 606 or transfer roller 606.

In a further process step, the corresponding isolating locations are separated by means of a mechanical separating apparatus 616 for carrying out a mechanical separating method (stamping, cutting, etc.). In various exemplary embodiments, the separating apparatus 616 may be designed, for example, as a stamping apparatus or as a laser. The alternating separating positions on the electrically non-conductive planar elements may be moved to by a movable separating apparatus 616 or else be obtained by the use of two separating units of the separating apparatus 616 that are offset relative to one another.

The apparatus 600 illustrated in FIG. 6 may merely be formed by the components arranged above the connector array 612 (designated as first partial apparatus 618) or also additionally have a second partial apparatus 620, which may be arranged opposite the first partial apparatus 618 with respect to the connector array 612, such that further electrically non-conductive planar elements may be applied, for example adhesively bonded, on to the solar cell connector elements (for example in the form of contact wires or contact ribbons).

In various exemplary embodiments, the second partial apparatus 620 may include an additional film roll 622 or film roller 622, from which an additional film 624, for example a plastic film 624, for example a self-adhesive plastic film 624, is provided, which is brought to an additional transfer roll 626 or additional transfer roller 626, where a further piece of film 628 of corresponding width is cut out or stamped by means of a cutting roller, for example. For this purpose, it is provided that the additional film 624 does not run continuously, but rather is conveyed in a step-by-step manner_{—} The residual film 630 remaining after the respective additional planar element 628 has been cut out (to which element the solar cell connector elements (for example in the form of contact wires or contact ribbons) from the connector array 612 are applied) may in turn be wound on to an additional roll 632 (also designated as residual film roll) or run directly into a supply container (not shown).

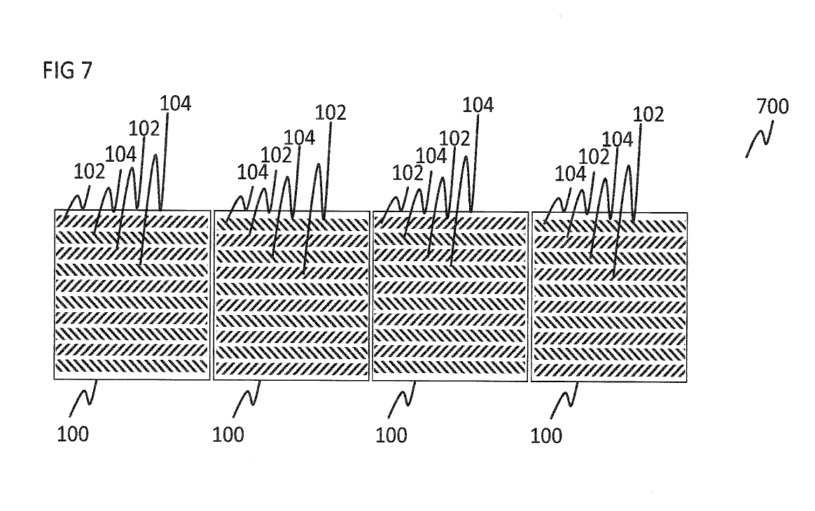

FIG. 7 shows an apparatus 700 including a plurality of solar cells 100 arranged alongside one another for series interconnection. For simpler elucidation, FIG. 7 only illustrates four solar cells 100, although in various exemplary embodiments any desired number, in principle, of solar cells 100 may be arranged alongside one another in the apparatus 700, for example 10, 15, 20, 25, 30, 35, 40, or more.

In various exemplary embodiments, the contact structures of the solar cells 100 are arranged in such a way that the number of emitter contacts 104 is equal to the number of base contacts 102. Prior to the interconnection (by means of one or a plurality of solar cell electrodes in accordance with various exemplary embodiments), the solar cells 100 are correspondingly oriented, such that, in the interconnection direction, a base contact 102 of a first solar cell 100 lies adjacent to an emitter contact 104 of the second solar cell 100 (which is arranged directly adjacent to the first solar cell 100).

In various exemplary embodiments, the base contacts 102 and the emitter contacts 104 may be arranged with respect to the center of the solar cell 100, such that, by rotating the solar cell 100 by 180° of one solar cell 100 with respect to an adjacent solar cell 100, the above-described orientation of the contacts 102, 104 with respect to one another can be achieved in a very simple and thus cost-effective manner. In various exemplary embodiments, the number of base contacts 102 and the number of emitter contacts 104 can be identical.

In various exemplary embodiments, as described, the solar cells 100, 200 are placed on to a transport belt and subsequently joined to form solar cell strings or complete solar cell matrices that are then processed further to form solar cell modules. In various exemplary embodiments, provision is made for performing the process continuously by (for example in the manner described above) prefabricated electrode material being supplied as continuous tape, or else the electrode material is produced simultaneously in the process. A batchwise mode of working is alternatively provided in various exemplary embodiments, by firstly all the solar cells of a solar cell string or else of an entire solar cell matrix being positioned on a suitable support and the prefabricated solar cell electrode subsequently being placed over the solar cells 100, 200 and being joined in a further step.

Optionally, the solar cells 100, 200 may also be positioned directly on to a front side material to which encapsulation material is applied, for example covering glass, ETFE (as one example of a fluoropolymer), etc. Afterward, the connector array may be emplaced and joined and this may be continued with the construction of the layup for the lamination. As a result, additional handling steps (solar cell string transport, solar cell matrix placement) could be dispensed with. The process may be performed in a batchwise manner, wherein the positioning of the solar cells may be effected in a step-by-step manner. When the desired number of solar cells has been positioned, in various exemplary embodiments the electrode tape is placed onto all the solar cells and joined.

In various exemplary embodiments, continuous performance of the process is also provided; in this case, the solar cells 100 and the electrode tape, to put it another way the solar cell electrode 400 prefabricated in the manner described above, are supplied and joined in a continuous process.

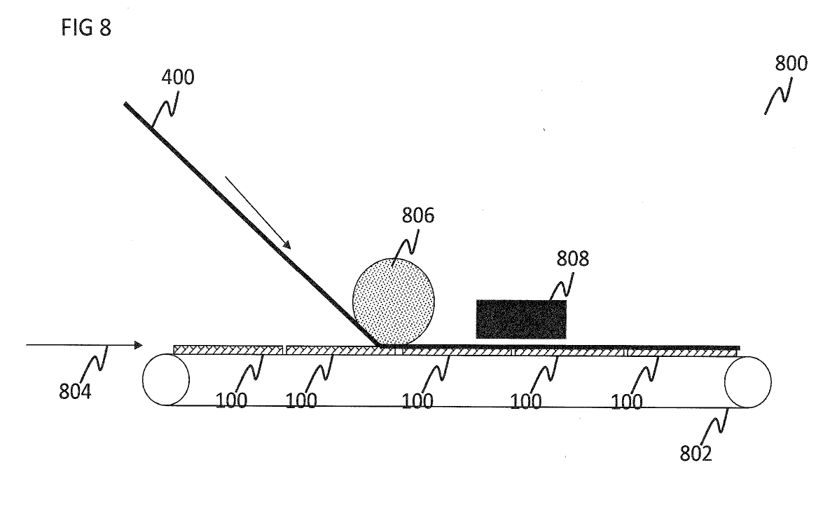

A joining device 800, designed for carrying out a continuous process for joining a solar cell electrode 400 placed on to the rear sides of a plurality of solar cells 100, in accordance with various exemplary embodiments, is illustrated in side view in FIG. 8.

In various exemplary embodiments, the joining device 800 may include a solar cell transport apparatus 802 (for example implemented as a conveyor belt 802), on which solar cells, for example solar cells 100 as illustrated in FIG. 1, are transported in a transport direction symbolized by means of an arrow 804 through the joining device 800. In various exemplary embodiments, the solar cells 100 are supplied by a solar cell supply device (not illustrated) of the joining device 800. The joining device 800 may furthermore include an electrode tape supply device 806, for example in the form of an electrode tape roller 806, which is arranged relative to the solar cell transport apparatus 802 in such a way that the solar cell electrode 400 supplied is deflected by means of the electrode tape supply device 806 in such a way that the one or the plurality of solar cell electrodes 400 is or are placed on to the rear side of the solar cells 100 in such a way that the individual electrically conductive solar cell connector elements 302 are placed on to the base contacts 102 or the emitter contacts 104. Furthermore, in various exemplary embodiments, the joining device 800 may include a joining apparatus 808, for example in the form of a soldering apparatus 808. The solar cells 100 on whose rear sides the one or the plurality of solar cell electrodes 400 has or have been placed are fed to the joining apparatus 808, where the individual electrically conductive solar cell connector elements 302 are fixed, for example soldered, to the base contacts 102 or the emitter contacts 104.

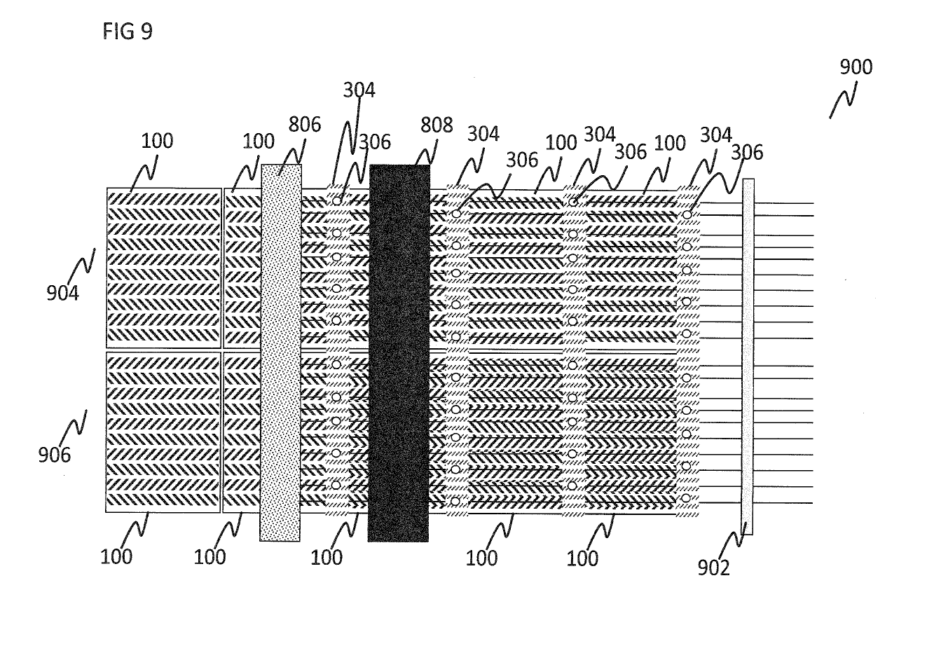

A joining device 900, designed for carrying out a continuous process for joining a solar cell electrode 400 placed on to the rear sides of a plurality of solar cells 100, in accordance with various exemplary embodiments, is illustrated in plan view in FIG. 9. The joining device 900 in accordance with FIG. 9 is similar to the joining device 800 in accordance with FIG. 8, but is dimensioned in such a way that a plurality of solar cell strings (for example two, in other exemplary embodiments three, four, five, six, seven, eight, nine, ten, or more) are formed simultaneously, in principle in the manner described above with reference to FIG. 8. Furthermore, FIG. 9 illustrates a cross-interconnection element 902, by means of which a plurality of solar cell strings 904, 906 are electrically coupled to one another, for example connected in parallel with one another. A series connection of adjacent solar cell strings 904, 906 is possible by means of an adapted arrangement of the isolating locations 306.

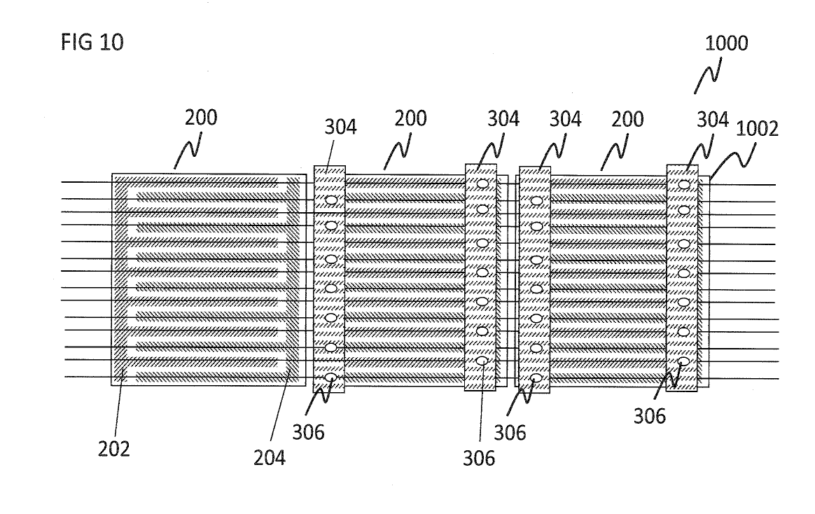

The processes described may be used for both contact structure arrangements, for example for solar cells 100 as illustrated in FIG. 1, or for solar cells 200 as illustrated in FIG. 2. Only the prefabrication of the electrode tape 400 is correspondingly adapted in various exemplary embodiments. In the case of solar cells 200 having an IBC contact structure, for example two solar cell connector element isolating locations are provided per solar cell 200 (as illustrated in a device 1000 in FIG. 10). In this case, the plastic film 304 simultaneously serves as an insulation layer. Furthermore, FIG. 10 shows a solar cell edge 1002.

As a result of the interconnection with the tape electrode described here, for example, in one or a plurality of solar cell electrodes 400, the conduction losses in the IBC contact structures are significantly reduced. The current no longer has to be transported through the thin contact structures with a high line resistance to the collecting structure, but rather can be transported through the connectors, for example one or a plurality of solar cell electrodes 400.

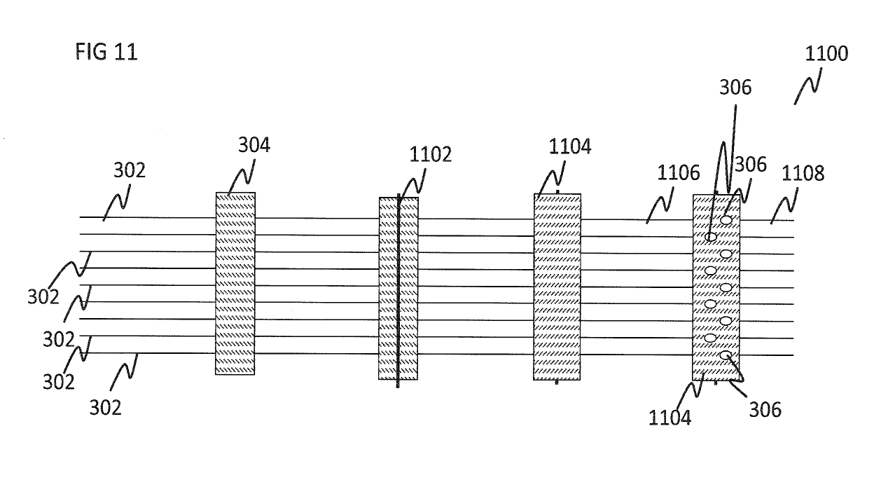

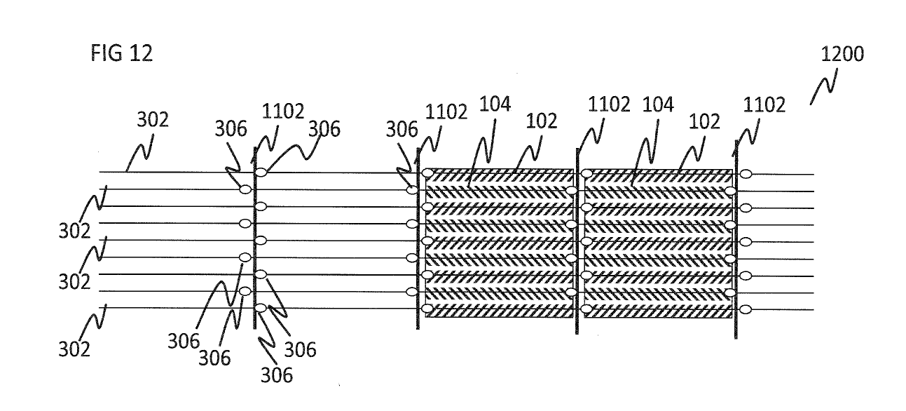

FIG. 11 and FIG. 12 show an interconnection 1100 of solar cells 100 having an unequal number of positive contact regions and negative contact regions, for example having an equal number of base contacts 102 and emitter contacts 104.

FIG. 11 illustrates the production of a solar cell electrode, according to various exemplary embodiments. Firstly, a first electrically non-conductive planar element 304 (for example a film, for example a plastic film) is applied to a multiplicity of electrically conductive solar cell connector elements 302 arranged alongside one another.

A transverse wire 1102 is then applied, for example adhesively bonded, on to a respective first electrically non-conductive planar element 304 (for example at an angle with respect to, for example transversely with respect to, the electrically conductive solar cell connector elements 302).

In various exemplary embodiments, optionally a second electrically non-conductive planar element 1104 may be applied to the first electrically non-conductive planar element 304 and the electrically conductive solar cell connector elements 302, such that the electrically conductive solar cell connector elements 302 are enclosed in a sandwich-like manner between the planar elements 304, 1104.

Afterward, in various exemplary embodiments, a respective solar cell connector element 302 can in each case be separated alternately on different sides of the transverse wire 1102, such that two partial solar cell connector elements 1106, 1108 electrically isolated from one another (by means of solar cell connector element isolating locations 306) are formed in each case.

FIG. 12 shows an illustration 1200 of solar cell connector element isolating locations 306 in accordance with various exemplary embodiments in accordance with FIG. 11 without the planar elements 304, 1104 for elucidating the current path in a solar cell string.

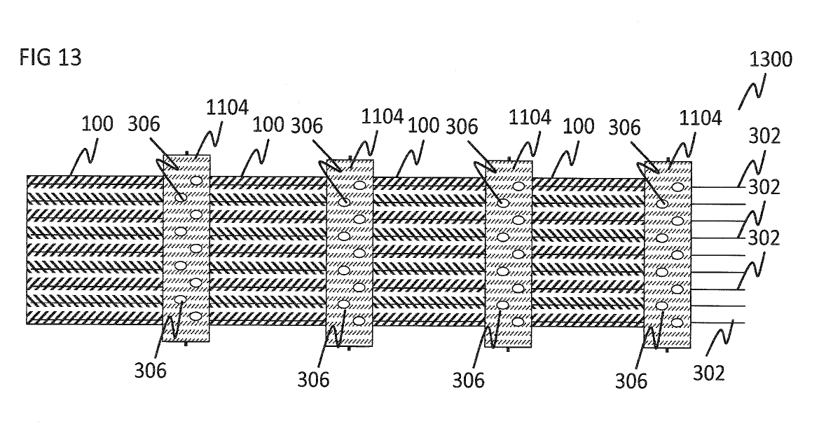

FIG. 13 shows an illustration 1300 of a plurality of solar cells 100 interconnected in accordance with the process illustrated in FIG. 11, in accordance with various exemplary embodiments.

In various exemplary embodiments, a solar cell electrode may have a length (i.e. a dimension in the longitudinal extent of the electrically conductive solar cell connector elements, for example of the contact wires or contact ribbons) which is greater than the length of a solar cell 100, 200. In various exemplary embodiments, a solar cell electrode may have a length which is substantially equal to or greater than the length of a plurality of solar cells 100, 200. In various exemplary embodiments, a solar cell electrode may have a length which is substantially equal to or greater than the length of a solar cell string. In various exemplary embodiments, a solar cell electrode may have a length which is substantially equal to or greater than the length of a solar cell module formed by the solar cells.

In various exemplary embodiments, a solar cell electrode may have a width (i.e. a dimension substantially transversely with respect to the longitudinal extent of the electrically conductive solar cell connector elements, for example of the contact wires or contact ribbons) which is greater than the width of a solar cell 100, 200. In various exemplary embodiments, a solar cell electrode may have a width which is substantially equal to or greater than the width of a plurality of solar cells 100, 200 arranged alongside one another (connected in parallel or in series). In various exemplary embodiments, a solar cell electrode may have a width which is substantially equal to or greater than the width of a solar cell module formed by the solar cells.

In various exemplary embodiments, a solar cell electrode may have a size such that a plurality or all of the solar cells of a solar cell module are interconnected with one another by means of exactly one solar cell electrode or exactly two solar cell electrodes or exactly three solar cell electrodes in accordance with various exemplary embodiments.

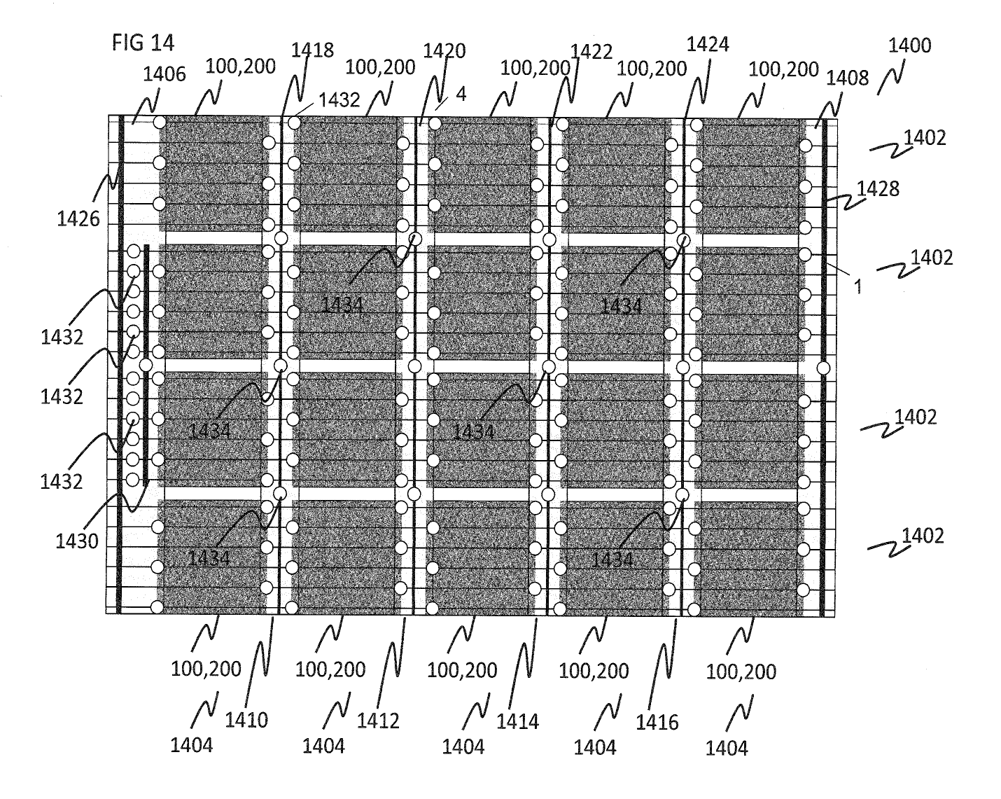

FIG. 14 shows a solar cell electrode 1400 in accordance with various exemplary embodiments, placed on to a plurality of solar cells 100, 200 of a solar cell module, for example on to all the solar cells 100, 200 of a solar cell module. Therefore, the solar cell electrode 1400 is dimensioned and designed for electrically interconnecting all the solar cells 100, 200 of a solar cell module. Consequently, in these exemplary embodiments, only exactly one solar cell electrode 1400 is required for electrically interconnecting all the solar cells 100, 200 of a solar cell module.

As illustrated in FIG. 14, the solar cells 100, 200 are arranged alongside one another in a matrix-type fashion in a plurality of rows 1402 and columns 1404. Accordingly, the solar cell electrode 1400 has a plurality of row regions each dimensioned such that each row region of a solar cell electrode 1400 in each case makes contact with the (for example all of the) contact regions 102, 104, 202, 204 of the solar cells of a row 1402, to put it another way of a solar cell string (for example is electrically connected in series with one another).

In various exemplary embodiments, the solar cell electrode 1400 includes a first electrically non-conductive planar edge element 1406 and a second electrically non-conductive planar edge element 1408. Between the solar cells (for example between in each case two solar cells 100, 200 directly adjacent to one another) of a respective row 1402 and between the two edge elements 1406, 1408, additional electrically non-conductive planar elements 1410, 1412, 1414, 1416 are arranged, which have substantially the same construction as the planar elements 304 described above. In various exemplary embodiments, each of the additional electrically non-conductive planar elements 1410, 1412, 1414, 1416 includes at least one electrically conductive contact element 1418, 1420, 1422, 1424 (for example composed of one metal or a plurality of metals and/or one or a plurality of metal alloys). Each of the two edge elements 1406, 1408 may furthermore include one or a plurality of cross-connector structures, for example respectively one or a plurality of global cross-connector structures 1426, 1428, which substantially run along the entire width (i.e. along all the rows 1402) of the respective edge element 1408, and/or respectively one or a plurality of local cross-connector structures 1430, which extend along only a part of the entire width (i.e. along all the rows 1402) of the respective edge element 1408, for example however along at least one part of at least two solar cells 100, 200, such that a plurality of solar cells 100, 200 are electrically connected to one another (for example connected in parallel or in series) by means of the at least one local cross-connector structure 1430.

Furthermore, the solar cell electrode 1400 in various exemplary embodiments includes solar cell connector element isolating locations 1432, 1434, for example first solar cell connector element isolating locations 1432, which are provided on the planar elements 1406, 1408, 1410, 1412, 1414, 1416 (including the edge elements 1406, 1408) and which separate the electrically conductive solar cell connector elements into solar cell connector partial elements electrically insulated from one another, and second solar cell connector element isolating locations 1434, which are provided on the planar elements 1406, 1408, 1410, 1412, 1414, 1416 (including the edge elements 1406, 1408) and which separate the electrically conductive contact elements 1418, 1420, 1422, 1424 or the cross-connector structures 1426, 1428, 1430 into partial contact elements or partial cross-connector structures electrically insulated from one another.

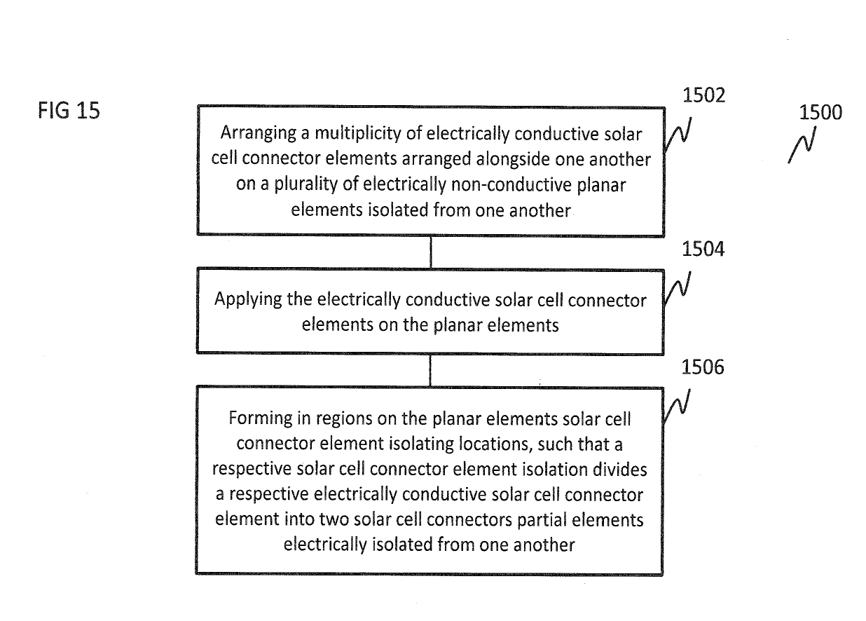

FIG. 15 shows a method for producing a solar cell connector electrode in accordance with various exemplary embodiments in a flow chart 1500.

In various exemplary embodiments, in 1502 a multiplicity of electrically conductive solar cell connector elements arranged alongside one another can be arranged on a plurality of electrically non-conductive planar elements isolated from one another. Furthermore, in 1504, the electrically conductive solar cell connector elements may be applied on the planar elements, and, in 1506, solar cell connector element isolating locations may be formed in regions on the planar elements, such that any respective solar cell connector element isolation divides a respective electrically conductive solar cell connector element into two solar cell connector partial elements electrically isolated from one another.

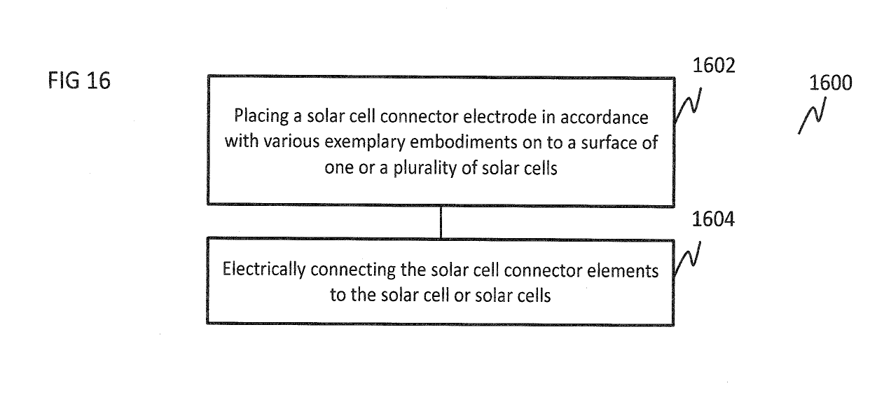

FIG. 16 shows a method for electrically connecting a plurality of solar cells in accordance with various exemplary embodiments in a flowchart 1600.

In various exemplary embodiments, in 1602, a solar cell connector electrode in accordance with various exemplary embodiments can be placed on to a surface of the solar cells, and, in 1604, the solar cell connector elements can then be electrically connected to the solar cells.

In one configuration, the solar cell connector elements may be soldered to the solar cells. In yet another configuration, the solar cells may have rear side contact cells and the solar cell connector electrode can be arranged and contact-connected exclusively on the rear side of the solar cells facing away from light. In yet another configuration, all the solar cells of a solar cell module may be electrically connected to a solar cell connector electrode shaped in matrix-type fashion.

In yet another configuration, each strip-shaped element can be or have been arranged in a manner crossing the electrically conductive solar cell connector elements.

In various exemplary embodiments, a first non-conductive planar element (for example in the form of an adhesive film), for example a lower element, of two non-conductive planar elements can be wider than the optional second non-conductive planar element. In these regions, the separation, for example the stamping, may be effected, for example.

In various exemplary embodiments, a tape-type electrode for interconnecting rear side contact cells is provided, which may be configured in such a way that a multiplicity of connector elements (ribbons or wire) substantially running parallel are fixed by a carrier element locally substantially in the solar cell interspace, and isolating locations are inserted in a targeted manner in the region of the film. The carrier element may be embodied by means of applying the connectors to a self-adhesive plastic film, for example, or by fusing the connectors in a hot melt, EVA, thermoplastics, etc. In various exemplary embodiments, the tape-type electrode may be provided with double-sided adhesive bonding, wherein the two sides either are completely congruent or else one side is larger (e.g. wider), and the electrodes are thereby locally mechanically fixed to the solar cells (strain relief, better fixing during the manufacturing process). In various exemplary embodiments, at least one adhesive film surface may be configured in such a way that further functionalities are provided (for example structuring for better light capture, aesthetic covering of the wires in the solar cell interspace). In various exemplary embodiments, it is possible to provide an adaptation to pseudo-square monocells by means of cut-out regions of different lengths.

In various exemplary embodiments, a solar cell module including such a tape electrode may be provided.

In various exemplary embodiments, a method for producing the tape electrode by adhesively bonding a connector array on to and/or between suitable adhesive strips is provided.

In various exemplary embodiments, a method for producing the tape electrode by fusion in an optionally modified hot melt adhesive strip, a thermoplastic strip, etc. is provided.

In various exemplary embodiments, a method for interconnecting and joining solar cells with a tape electrode independently before the layup placement of the electrode is provided. The joining can be configured as a continuous process and/or as a batchwise process.

In various exemplary embodiments, a method for interconnecting and joining solar cells with a tape electrode as a partial step of the layup placement (placement of the cells on front side with embedding material and subsequent joining) is provided. The process may be configured as a continuous process and/or as a batchwise process.

Illustratively, in various exemplary embodiments, a contact-connection of solar cells, for example rear side contact solar cells, by means of a specifically structured electrode is provided, wherein the prefabricated electrode can be made available in a continuous tape, for example, or can be produced simultaneously with the process. The solar cells may be interconnected by a suitable joining process in a continuous process and also in a batchwise process.

In various exemplary embodiments, a solar cell connector electrode is provided. The solar cell connector electrode may include a multiplicity of electrically conductive solar cell connector elements arranged alongside one another; and a plurality of electrically non-conductive and, preferably isolated from one another, planar elements on which the electrically conductive solar cell connector elements are arranged; wherein solar cell connector element isolating locations are provided in regions on the planar elements, such that by means of a respective solar cell connector element isolating location, a respectively electrically conductive solar cell connector element is divided into a plurality of, preferably two, solar cell connector partial elements electrically isolated from one another.

In one configuration, the solar cell connector elements may be embodied as solar cell connector wires and/or as solar cell connector tapes.

In yet another configuration, the multiplicity of solar cell connector elements may have 5 to 60 solar cell connector elements.

In yet another configuration, the solar cell connector elements may be arranged substantially parallel to one another.

In yet another configuration, the planar elements may be arranged substantially in strip-shaped fashion and transversely with respect to the solar cell connector elements.

In yet another configuration, the electrically conductive solar cell connector elements may be adhesively connected to the planar elements.

In yet another configuration, the planar elements may be produced from plastic film.

In yet another configuration, the planar elements may be produced from self-adhesive plastic film.

In yet another configuration, at least one planar element may be dimensioned in such a way that a plurality of solar cells may be interconnected with one another in a series circuit or a parallel circuit or else in any desired combination of series circuit and parallel circuit by means of the multiplicity of electrically conductive solar cell connector elements.

In yet another configuration, at least one additional solar cell connector element isolating location may be provided in a region on the at least one planar element, such that the electrically conductive cross-connector structure is divided into two cross-connector partial elements electrically isolated from one another.

In yet another configuration, at least one additional solar cell connector element isolating location may be provided in a region on the at least one planar element, such that the electrically conductive cross-connector structure is divided into two cross-connector partial elements electrically isolated from one another between two solar cells to be interconnected.

In yet another configuration, the solar cell connector electrode may furthermore include additional planar elements applied on the planar elements in such a way that the solar cell connector elements are arranged between the planar elements and the additional planar elements.

In yet another configuration, the solar cell connector element isolating locations may be provided on a respective solar cell connector element in such a way that the solar cell connector elements directly adjacent to a solar cell connector element provided with a solar cell connector element isolating location are free of solar cell connector element isolating locations.

In yet another configuration, isolating locations may be arranged in the region of a planar element on every second solar cell connector element.

In yet another configuration, an electrically conductive cross-connector structure may be provided on at least one planar element, and electrically connects at least two of the solar cell connector elements to one another.

In various exemplary embodiments, a solar cell module is provided. The solar cell module may include a plurality of solar cells; and at least one solar cell connector electrode in accordance with various exemplary embodiments such as has been described above or will be explained below. A plurality of solar cells may be connected in a series by means of the solar cell connector electrode.

In one configuration, the solar cell connector electrode may have a matrix-type assemblage and solar cells may be connected in a plurality of series by means of a plurality of solar cell connector electrodes in accordance with various exemplary embodiments such as has been described above or will be explained below.

In yet another configuration, the plurality of solar cells may have rear side contact cells and the solar cells may be connected by means of the at least one solar cell connector electrode exclusively on the sides facing away from light.

In various exemplary embodiments, a method for producing a solar cell connector electrode is provided. In accordance with the method, a multiplicity of electrically conductive solar cell connector elements arranged alongside one another may be arranged on a plurality of electrically non-conductive and, preferably isolated from one another, planar elements; and the electrically conductive solar cell connector elements may be applied on the planar elements; and solar cell connector element isolating locations may be formed in regions on the planar elements, such that, by means of a respective solar cell connector element isolation, a respective electrically conductive solar cell connector element is divided into a plurality of, for example two, solar cell connector partial elements electrically isolated from one another.

In one configuration, the solar cell connector elements may be embodied as solar cell connector wires and/or as solar cell connector tapes.

In yet another configuration, the solar cell connector elements may be arranged substantially parallel to one another.

In yet another configuration, the planar elements may be arranged substantially transversely with respect to the solar cell connector elements.

In yet another configuration, the electrically conductive solar cell connector elements may be adhesively bonded on the planar elements.

In yet another configuration, the planar elements may be produced from plastic film.

In yet another configuration, the planar elements may be produced from self-adhesive plastic film.

In yet another configuration, additional strip-shaped elements may be applied on the planar elements in such a way that the solar cell connector elements are arranged between the planar elements and the additional planar elements.

In yet another configuration, the solar cell connector element isolating locations may be formed on a respective solar cell connector element in such a way that the solar cell connector elements directly adjacent to a solar cell connector element provided with a solar cell connector element isolating location are free of solar cell connector element isolating locations.

In yet another configuration, an electrically conductive cross-connector structure may be formed on at least one planar element, and electrically connects at least two of the solar cell connector elements to one another.

In various exemplary embodiments, a method for electrically connecting a plurality of solar cells is provided. In accordance with the method, a solar cell connector electrode in accordance with various exemplary embodiments such as has been described above or will be explained below may be placed on to a surface of the solar cells. The solar cell connector elements may then be electrically connected to the solar cells.

In one configuration, the solar cell connector elements may be soldered to the solar cells.

In yet another configuration, the solar cells may have rear side contact cells and the solar cell connector electrode may be arranged and contact-connected exclusively on the rear side of the solar cells facing away from light.

In yet another configuration, all the solar cells of a solar cell module may be electrically connected to a solar cell connector electrode shaped in matrix-type fashion.

In various configurations, the solar cell may be embodied as a metal wrap-through (MWT) solar cell. In various configurations, the solar cell may be embodied as an emitter wrap-through (EWT) solar cell. In various configurations, the solar cell may be embodied as a back-junction solar cell.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A solar cell connector electrode, comprising:
a multiplicity of electrically conductive solar cell connector elements arranged alongside one another; and
a plurality of electrically non-conductive and isolated from one another, planar elements on which the electrically conductive solar cell connector elements are arranged;
wherein solar cell connector element isolating locations are provided in regions on the planar elements, such that, by means of a respective solar cell connector element isolating location, a respectively electrically conductive solar cell connector element is divided into a plurality of, preferably two, solar cell connector partial elements electrically isolated from one another.

2. The solar cell connector electrode as claimed in claim 1,
wherein the solar cell connector elements are embodied as at least one of solar cell connector wires and/or as solar cell connector tapes.

3. The solar cell connector electrode as claimed in claim 1,
wherein the solar cell connector elements are arranged substantially parallel to one another.

4. The solar cell connector electrode as claimed in claim 1,
wherein the planar elements are arranged substantially in strip-shaped fashion and transversely with respect to the solar cell connector elements.

5. The solar cell connector electrode as claimed in claim 1,
wherein the electrically conductive solar cell connector elements are adhesively connected to the planar elements.

6. The solar cell connector electrode as claimed in claim 1, further comprising:
additional planar elements applied on the planar elements in such a way that the solar cell connector elements are arranged between the planar elements and the additional planar elements.

7. The solar cell connector electrode as claimed in claim 1,
wherein the solar cell connector element isolating locations are provided on a respective solar cell connector element in such a way that the solar cell connector elements directly adjacent to a solar cell connector element provided with a solar cell connector element isolating location are free of solar cell connector element isolating locations.

8. The solar cell connector electrode as claimed in claim 1,
wherein an electrically conductive cross-connector structure is provided on at least one planar element, and electrically connects at least two of the solar cell connector elements to one another.

9. The solar cell connector electrode as claimed in claim 1,
wherein at least one planar element is dimensioned in such a way that a plurality of solar cells can be interconnected with one another in at least one of a parallel circuit and in a series circuit by means of the multiplicity of electrically conductive solar cell connector elements.

10. The solar cell connector electrode as claimed in claim 8,
wherein at least one additional solar cell connector element isolating location is provided in a region on the at least one planar element, such that the electrically conductive cross-connector structure is divided into two cross-connector partial elements electrically isolated from one another.

11. The solar cell connector electrode as claimed in claim 10,
wherein at least one additional solar cell connector element isolating location is provided in a region on the at least one planar element, such that the electrically conductive cross-connector structure is divided into two cross-connector partial elements electrically isolated from one another between two solar cells to be interconnected.

12. A solar cell module, comprising:
a plurality of solar cells; and
at least one solar cell connector electrode, the solar cell connector electrode comprising:
a multiplicity of electrically conductive solar cell connector elements arranged alongside one another; and
a plurality of electrically non-conductive and isolated from one another, planar elements on which the electrically conductive solar cell connector elements are arranged;
wherein solar cell connector element isolating locations are provided in regions on the planar elements, such that, by means of a respective solar cell connector element isolating location, a respectively electrically conductive solar cell connector element is divided into a plurality of, preferably two, solar cell connector partial elements electrically isolated from one another;
wherein a plurality of solar cells are connected in a series by means of the solar cell connector electrode.

13. The solar cell module as claimed in claim 12,
wherein the solar cell connector electrode has a matrix-type assemblage and solar cells are connected in a plurality of series by means of a plurality of solar cell connector electrodes, wherein at least one planar element of each solar cell connector electrode is dimensioned in such a way that a plurality of solar cells can be interconnected with one another in at least one of a parallel circuit and in a series circuit by means of the multiplicity of electrically conductive solar cell connector elements.

14. The solar cell module as claimed in claim 12,
wherein the plurality of solar cells have rear side contact cells and the solar cells are connected by means of the at least one solar cell connector electrode exclusively on the sides facing away from light.

15. A method for electrically connecting a plurality of solar cells, the method comprising:
placing a solar cell connector electrode onto a surface of the solar cells, the solar cell connector electrode comprising:
a multiplicity of electrically conductive solar cell connector elements arranged alongside one another; and
a plurality of electrically non-conductive and isolated from one another, planar elements on which the electrically conductive solar cell connector elements are arranged;
wherein solar cell connector element isolating locations are provided in regions on the planar elements, such that, by means of a respective solar cell connector element isolating location, a respectively electrically conductive solar cell connector element is divided into a plurality of, preferably two, solar cell connector partial elements electrically isolated from one another;
electrically connecting the solar cell connector elements to the solar cells.

16. The method as claimed in claim 15,
wherein the solar cell connector elements are soldered to the solar cells.

17. The method as claimed in claim 15,
wherein the solar cells have rear side contact cells and the solar cell connector electrode is arranged and contact-connected exclusively on the rear side of the solar cells facing away from light.

18. The method as claimed in claim 15,
wherein all the solar cells of a solar cell module are electrically connected to a solar cell connector electrode shaped in matrix-type fashion.
